(19) United States
(12) Patent Application Publication
(10) Pub. No.: US 2002/0155721 A1
(43) Pub. Date: Oct. 24, 2002

(54) Method of forming shallow trench isolation structure

(75) Inventors: Chun-Chi Wang, Nantou (TW); Chun-Lien Su, Tainan Hsien (TW); Gen-Da You, Ilan (TW)

Correspondence Address: LOWE HAUPTMAN GOPSTEIN GILMAN & PERNER, LLP, Suite 310, 1700 Diagonal Road, Alexandria, VA, 22314, US

(73) Assignee: MACRONIX INTERNATIONAL CO., LTD

(21) Appl. No.: 09/824,014

(22) Filed: Apr. 3, 2001

(51) Int. Cl. H01L 21/76; H01L 21/311

(52) U.S. Cl. 438/700; 438/703

(57) ABSTRACT

A method of forming a shallow trench isolation (STI) structure is disclosed. Instead of using a conventional chemical mechanical polishing (CMP), a wet etching is used in the present invention while forming a shallow trench isolation structure. By using the high selectivity of the wet etching, the thickness of the silicon nitride (Si₃N₄) layer and the oxide layer in the shallow trench isolation structure can be decreased or controlled, and the micro-scratch caused by the chemical mechanical polishing can be avoided.

### FIELD OF THE INVENTION

The present invention relates to a method of forming a shallow trench isolation (STI) structure, and more particularly, to a method of forming a shallow trench isolation structure by using a wet etching method.

### BACKGROUND OF THE INVENTION

In the very large scale integration (VLSI) process, an integrated circuit is usually composed of many metal oxide semiconductor (MOS) transistors. There are three kinds of the MOS transistors, the N-channel MOS (NMOS) transistor, the P-channel MOS (PMOS) transistor, and the complementary MOS (CMOS) transistor, wherein the CMOS transistor is composed of the NMOS transistor and the PMOS transistor. As the increasing of the integration of the semiconductor devices, the CMOS transistor that consumes less energy is being substituted for the NMOS transistor and the PMOS transistor gradually, and is becoming the most used MOS transistor.

In the use of the CMOS transistor, the NMOS transistor and the PMOS transistor in the CMOS transistor have to be isolated in order to prevent the function of the CMOS transistor from disappearing temporarily or permanently, i.e. resulting in latching up. In the recent semiconductor process, the trench isolation is an isolation technique applied wide to the CMOS transistor.

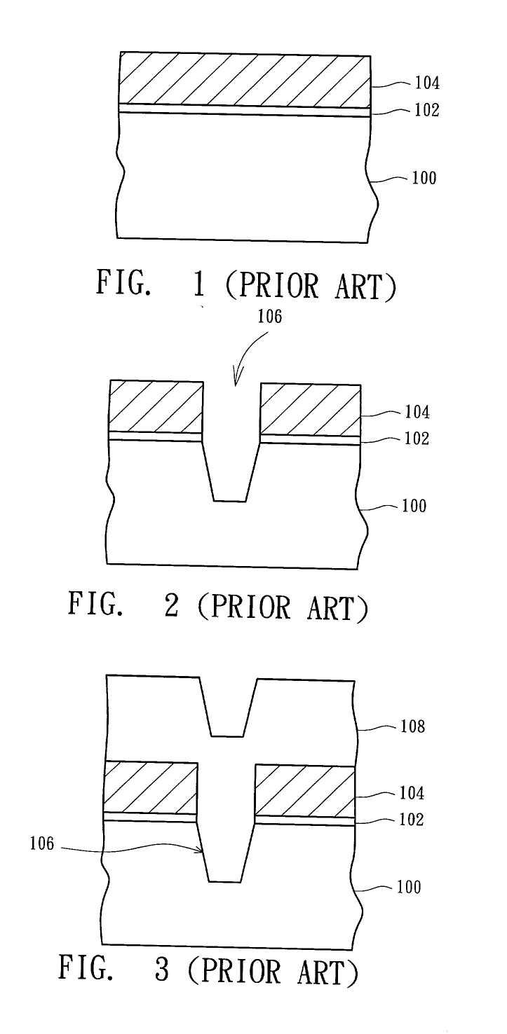

Referring to FIG. 1 to FIG. 5, showing the cross-sectional diagrams of conventional forming a shallow trench isolation structure on the substrate. Firstly, the thermal oxide layer 102 with the thickness of about hundred Å composed of silicon dioxide is formed as the oxide layer on the substrate 100 by the furnace process. Therein, the thermal oxide layer 102 is also called as the pad oxide layer, as a result of the weaker adhesive force of the silicon nitride to the silicon, so that a layer of the silicon dioxide is formed on the silicon substrate to assist the deposition of the silicon nitride before depositing the silicon nitride. Subsequently, the silicon nitride layer 104 is deposited on the thermal oxide layer 102, for example, by the low pressure chemical vapor deposition (LPCVD), as shown in FIG. 1.

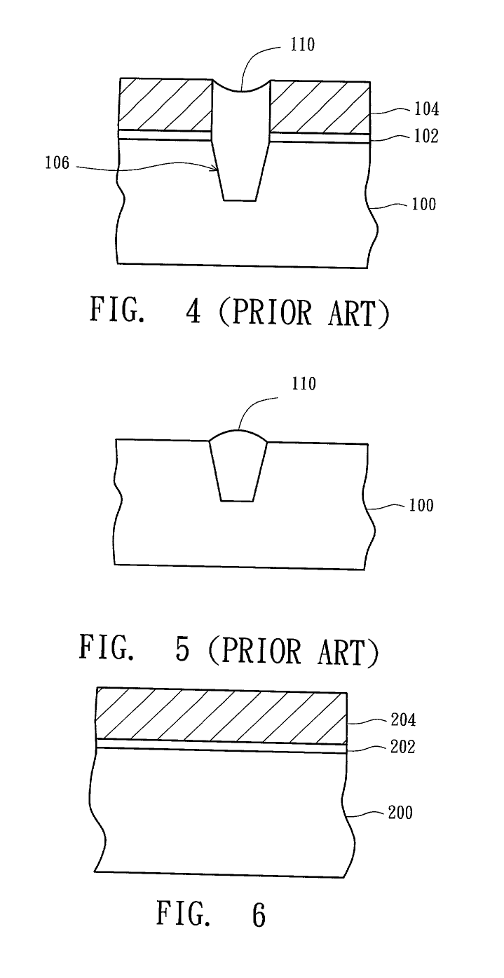

Then, the active area and the shallow trench 106 are defined on the substrate 100, for example, by the photolithography and the dry etching, and the structure is formed as shown in FIG. 2. Referring to FIG. 3, after the shallow trench 106 is defined, an oxide layer 108 is deposited by the chemical vapor deposition and covers the shallow trench 106 and the silicon nitride layer 104.

Referring to FIG. 4, the oxide layer 108 is polished subsequently by the chemical mechanical polishing and the polishing is stopped until the underlying silicon nitride layer 104 is about exposed. Thereafter, the silicon nitride layer 104 is stripped by the clean bench and by the high selectivity of the hot phosphoric acid (H₃PO₄) used in the clean bench. Then, the thermal oxide layer 102 is removed by the wet etching while using the hydrofluoric acid (HF) as the etching solution, so that the shallow trench isolation structure 110 as shown in FIG. 5 is formed.

In the process of forming the shallow trench isolation structure described above, the chemical mechanical polishing process not only costs too much but also has to utilize the reaction between the slurry of chemical solution and the layer's surface, and the particles of the slurry can cause lots of micro-scratch on the surface of the shallow trench isolation structure so that the active area is damaged. In addition, the stress induced by the thicker silicon nitride layer causes great damage to the thinner thermal oxide layer and the oxide layer of the flash memory, however, the conventional chemical mechanical polishing process can't reduce or control effectively the thickness of the silicon nitride layer and the oxide layer of the shallow trench isolation structure.

SUMMARY OF THE INVENTION

According to the conventional method of forming the shallow trench isolation structure, the chemical mechanical polishing process costs too much and the slurry causes many micro-scratch on the surface of the shallow trench isolation structure and damages the active area. In addition, the chemical mechanical polishing process can't reduce or control effectively the thickness of the silicon nitride layer and the oxide layer. It is therefore, the stress problem is induced by the silicon nitride layer.

Accordingly, one aspect of the invention is to provide a method of forming the shallow trench isolation structure, the method of the present invention takes the wet etch to replace the chemical mechanical polishing process used in the conventional method. The chemical mechanical polishing process costs too much and the particles of slurry used in the process can cause many micro-scratch on the surface of the shallow trench isolation structure. Accordingly, the present invention can reduce the process cost, avoid the micro-scratch caused by the slurry, and enhances the throughput yield.

Another aspect of the invention is to provide a method of forming the shallow trench isolation structure, the wet etching used in the method of the present invention has high selectivity so that the thickness of the silicon nitride layer and the oxide layer of the shallow trench isolation structure can be reduced or controlled, and can avoid the stress caused by the silicon nitride layer to damage the thermal oxide layer and the oxide layer of the flash memory.

For at least the foregoing aspects discussed above, the present invention provides a method of forming the shallow trench isolation structure. While forming the shallow trench isolation structure in the integrated circuits, the method of the present invention etches the oxide layer on the first silicon nitride layer of the active area by the wet etching until the first silicon nitride layer is about exposed. Then, the second silicon nitride layer is deposited, and subsequently a photoresist is formed on the second silicon nitride layer to cover the whole shallow trench area. Portions of the second silicon nitride layer and the oxide layer are removed by the photolithography and dry etching until the first silicon nitride layer underlying is about exposed, and the photoresist is stripped by using the wet strip or the dry strip. Afterward, both the silicon nitride layers is stripped by using the hot phosphoric acid in the wet bench, and the thermal oxide layer is removed by the wet etching while using the hydrofluoric acid as the etching solution, so that the shallow trench isolation structure is formed. Therefore, the shallow trench isolation structure can be obtained without the chemical mechanical polishing process by employing the present invention, and not only the process cost can be reduced but also the yield can be enhanced. Furthermore, the thickness of the silicon nitride layer and the oxide layer can be controlled, and the stress problem resulted from the thick silicon nitride layer can be avoided in the present invention.

BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a cross-sectional view of a conventional substrate having a thermal oxide layer and a silicon nitride layer formed thereon;

FIG. 2 is a cross-sectional view of a conventional structure after a shallow trench is defined;

FIG. 3 is a cross-sectional view of the conventional structure after an oxide layer is deposited by the chemical vapor deposition;

FIG. 4 is a cross-sectional view of the conventional structure after polishing by the chemical mechanical polishing;

FIG. 5 is a cross-sectional view of the conventional shallow trench isolation structure;

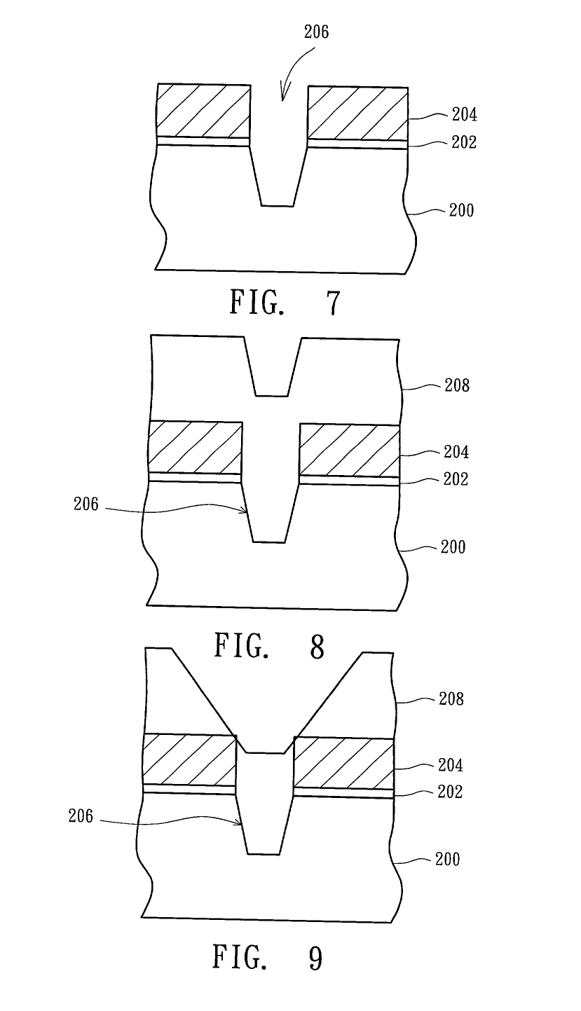

FIG. 6 is a cross-sectional view of a substrate having a thermal oxide layer and a silicon nitride layer formed thereon in accordance with a preferred embodiment of the present invention;

FIG. 7 is a cross-sectional view of a structure after a shallow trench is defined in accordance with a preferred embodiment of the present invention;

FIG. 8 is a cross-sectional view of the structure after an oxide layer is deposited by the chemical vapor deposition in accordance with a preferred embodiment of the present invention;

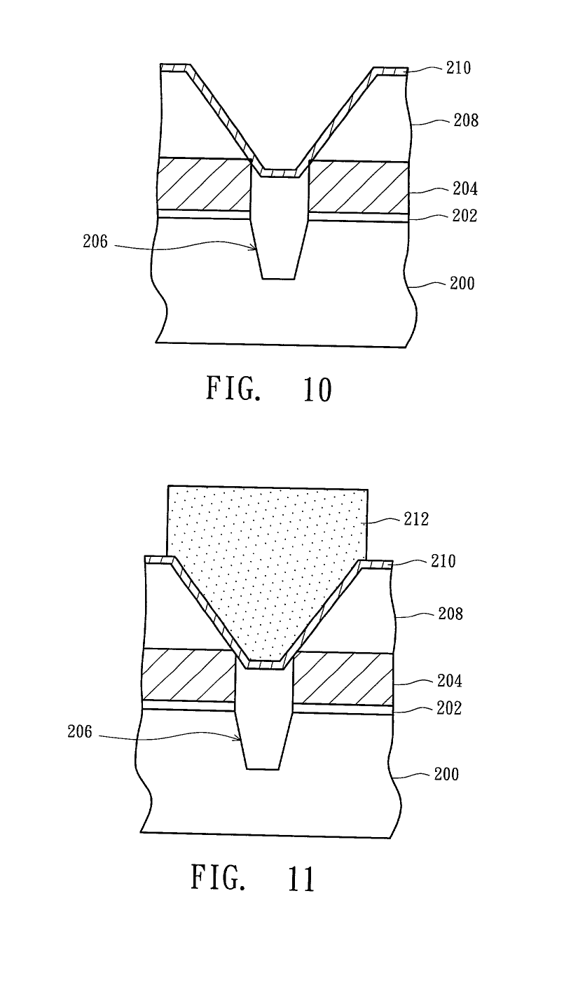

FIG. 9 is a cross-sectional view of the structure after wet etching in accordance with a preferred embodiment of the present invention;

FIG. 10 is a cross-sectional view of the structure after a silicon nitride layer is deposited again in accordance with a preferred embodiment of the present invention;

FIG. 11 is a cross-sectional view of the structure after a photoresist covers the shallow trench isolation area in accordance with a preferred embodiment of the present invention;

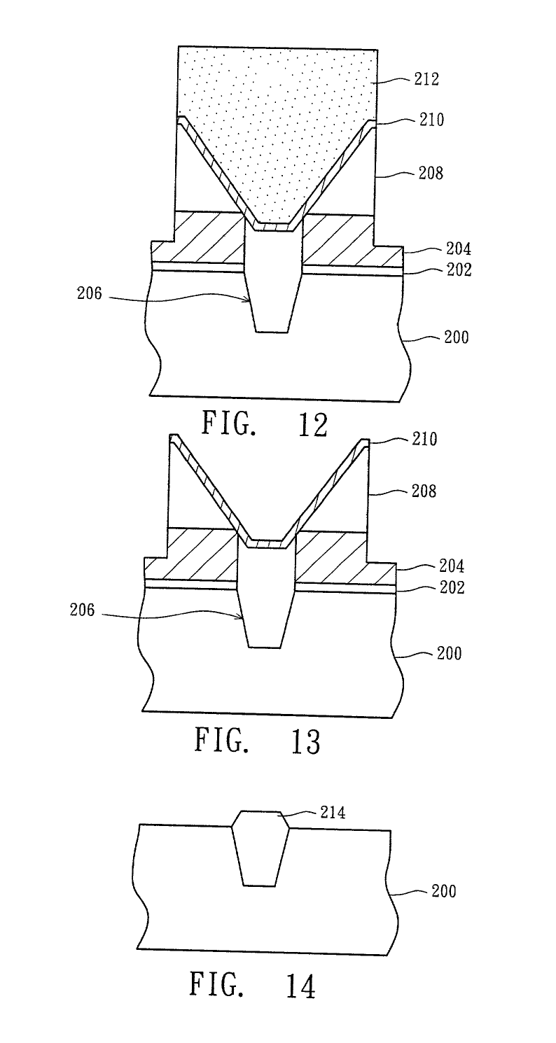

FIG. 12 is a cross-sectional view of the structure after dry etching in accordance with a preferred embodiment of the present invention;

FIG. 13 is a cross-sectional view of the structure after the photoresist is stripped in accordance with a preferred embodiment of the present invention; and

FIG. 14 is a cross-sectional view of the shallow trench isolation structure in accordance with a preferred embodiment of the present invention.

### DETAILED DESCRIPTION OF THE PREFERRED DRAWINGS

While forming the shallow trench isolation structure in the integrated circuits in the past, it had to use the chemical mechanical polishing process to polish the oxide layer on the silicon nitride layer of the active area. Due to the high cost of the chemical mechanical polishing process and the instability of the slurry used in the chemical mechanical polishing process, the process is difficult to achieve uniformity, therefore, in order to avoid using the chemical mechanical polishing process, the present invention provides a method to form the shallow trench isolation structure by wet etching, as described below.

Referring to FIG. 6 to FIG. 14, showing the cross-sectional diagrams of forming a shallow trench isolation structure on the substrate in accordance with a preferred embodiment of the present invention. Firstly, the thermal oxide layer 202 with the thickness of about hundred Å composed of silicon dioxide is formed as the device oxide layer on the substrate 200 by the furnace process. Therein, the thermal oxide layer 202 is also called as the pad oxide layer, as a result of the weaker adhesive force of the silicon nitride to the silicon, so that a layer of the silicon dioxide is formed on the silicon substrate to assist the deposition of the silicon nitride before depositing the silicon nitride. Then, the silicon nitride layer 204 is deposited on the thermal oxide layer 202, for example, by the low pressure chemical vapor deposition, and the structure is formed as shown in FIG. 6.

Subsequently, the active area and the shallow trench 206 are defined on the substrate 200, for example, by the photolithography and the dry etching, as shown in FIG. 7. Referring to FIG. 8, after defining the shallow trench 206, an oxide layer 208 is deposited by the chemical vapor deposition and covers the shallow trench 206 and the silicon nitride layer 204.

Referring to FIG. 9, the oxide layer 208 is etched by the wet etching until the silicon nitride layer 204 above the edge of the shallow trench 206 is about exposed, and the selectivity between the silicon nitride and oxide of the wet etching is high so that the end point of the etching can be controlled. In a preferred embodiment of the present invention, after the wet etching process is completed, the silicon nitride layer 210 is deposited, for example, by the chemical vapor deposition to cover the entire surface of the oxide layer 208, the shallow trench 206, and the exposed silicon nitride layer 204 above the edge of the shallow trench 206, and the structure as shown in FIG. 10 is formed. However, it is worthy noted that the silicon nitride layer 210 is not necessary to be formed while the wet etching process is completed in the present invention. The purpose of forming the silicon nitride layer 210 is just to better control the thickness of the shallow trench isolation structure 214.

The character of the present invention is that the thickness of the oxide layer 208 can be controlled effectively by using the wet etching process, and it is needless to form a thicker silicon nitride layer while comparing to the conventional chemical mechanical polishing process.

Referring to FIG. 11, a photoresist 212 is formed on the silicon nitride layer 210 to cover the whole shallow trench 206, and then performs a photolithography step on the photoresist 212 by using a photo-mask. Subsequently, portions of the silicon nitride layer 210 and the oxide layer 208 is removed by the etch, such as dry etching, until the silicon nitride layer 204 underlying is about exposed, as shown in FIG. 12.

Referring to FIG. 13, after the dry etching process, the photoresist 212 is stripped by using the wet strip or the dry strip so that the silicon nitride layer 210 is exposed. Subsequently, the silicon nitride layer 204 and the silicon nitride layer 210 is stripped by hot phosphoric acid in a wet bench. In addition, the oxide layer 208 between the silicon nitride layer 204 and the silicon nitride layer 210 is also stripped. And the thermal oxide layer 202 is removed by the wet etching while using the hydrofluoric acid as the etching solution, so that the completed shallow trench isolation structure 214 is formed, as shown in FIG. 14.

The advantage of the present invention is to provide a method of forming the shallow trench isolation structure in the integrated circuits process, it is not necessary for the method of the present invention to use the chemical mechanical polishing process, so that the process cost can be reduced by employing the present invention and the micro-scratch formed on the surface of the shallow trench isolation structure that are caused by the particles of the slurry in the chemical mechanical polishing process can be avoided to decrease the yield. In addition, the wet etching used in the method of the present invention has high selectivity between the silicon nitride and the oxide, so that the thickness of the silicon nitride layer and the oxide layer of the shallow trench isolation structure can be reduced or controlled, and the stress induced by the silicon nitride layer to damage the thermal oxide layer and the oxide layer of the flash memory can be prevented.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A method of forming a shallow trench isolation structure, comprising:
forming an oxide layer to cover a substrate, wherein the substrate has a first silicon nitride layer formed thereon, and a shallow trench is located in the substrate and the first silicon nitride layer;
performing a wet etching step to etch the oxide layer until the first silicon nitride layer is about exposed;
forming a second silicon nitride layer to cover the oxide layer and the first silicon nitride layer;
forming a photoresist to cover the second silicon nitride layer;
defining the photoresist, and etching a portion of the second silicon nitride layer and the oxide layer; and
removing the photoresist, the second silicon nitride layer, and the first silicon nitride layer.

2. The method according to claim 1, wherein the oxide layer covers the first silicon nitride layer and the shallow trench, and fills the shallow trench in the forming step of the oxide layer.

3. The method according to claim 1, wherein the step of forming the oxide layer is performed by a chemical vapor deposition.

4. The method according to claim 1, wherein the step of defining the shallow trench is performed by a dry etching.

5. The method according to claim 1, wherein the step of etching the portion of the second silicon nitride layer and the oxide layer is performed by a dry etching.

6. The method according to claim 1, wherein the step of removing the second silicon nitride layer and the first silicon nitride layer is performed by a clean bench.

7. The method according to claim 6, wherein the clean bench uses a thermal phosphoric acid as a clean solution.

8. The method according to claim 1, wherein the oxide layer between the second silicon nitride layer and the first silicon nitride layer is also removed after the second silicon nitride layer and the first silicon nitride layer are removed.

9. A method of forming a shallow trench isolation structure, comprising:
forming an oxide layer to cover a substrate, wherein the substrate has a silicon nitride layer formed thereon, and a shallow trench is located in the substrate and the silicon nitride layer;
performing a wet etching step to etch the oxide layer until the silicon nitride layer is about exposed;
forming a photoresist to cover the oxide layer;
defining the photoresist, and etching a portion of the oxide layer until the silicon nitride layer is exposed; and
removing the photoresist and the silicon nitride layer.

10. The method according to claim 9, wherein the oxide layer covers the silicon nitride layer and the shallow trench, and fills the shallow trench in the forming step of the oxide layer.

11. The method according to claim 9, wherein the step of forming the oxide layer is performed by a chemical vapor deposition.

12. The method according to claim 9, wherein the step of defining the shallow trench is performed by a dry etching.

13. The method according to claim 9, wherein the step of removing the oxide layer is performed by a dry etching.

14. The method according to claim 9, wherein the step of removing the silicon nitride layer is performed by a clean bench.

15. The method according to claim 14, wherein the clean bench uses a thermal phosphoric acid as a clean solution.

16. The method according to claim 9, wherein the oxide layer on the silicon nitride layer is removed after the silicon nitride layer is removed.

17. A method of forming a shallow trench isolation structure, comprising:
providing a substrate, and the substrate has a first silicon nitride layer thereon;
defining a shallow trench on the substrate by a dry etch;
forming an oxide layer to cover the first silicon nitride layer and the shallow trench by a chemical vapor deposition;
performing a wet etch step to etch the oxide layer until the first silicon nitride layer is about exposed;
forming a second silicon nitride layer to cover the oxide layer and the first silicon nitride layer;
forming a defined photoresist on the second silicon nitride layer;
etching the second silicon nitride layer and the oxide layer until the first silicon nitride layer is about exposed; and
removing the second silicon nitride layer, the oxide layer, and the first silicon nitride layer by a clean bench.

18. The method according to claim 17, wherein the clean bench uses a thermal phosphoric acid as a clean solution.
